(19) United States
(12) Patent Application Publication
(10) Pub. No.: US 2005/0062037 A1
(43) Pub. Date: Mar. 24, 2005

(54) Electrical conductor

(76) Inventor: Nico Naas, Karlsruhe (DE)

Correspondence Address: Patrick J O'Shea;Gauthier & Connors, Suite 3300, 225 Franklin Street, Boston, MA, 02110, US

(21) Appl. No.: 10/494,576

(22) PCT Filed: Oct. 23, 2002
(86) PCT No.: PCT/EP02/11841

(51) Int. Cl. H01L 29/08; H01L 35/24

(52) U.S. Cl. 257/40

(57) ABSTRACT

In order to combine high flexibility and complete electromagnetic shielding in an electrical line comprising at least one insulated conductor (A) surrounded by an insulation layer (1), an exposed ground conductor (MA) is provided at at least one site (F). A metal layer (MS) is applied by vapor deposition onto the line, said layer being applied directly onto the ground conductor (MA) at the exposed site (F). Alternatively, the ground conductor may be completely exposed. In another embodiment of the invention, the vapor-deposited metal layer (MS) is used as a ground conductor.

The invention relates to an electrical line which comprises at least one insulated conductor.

In order to provide shielding from electromagnetic fields, electrical lines are, for example, surrounded by a braid of electrically conductive material. The braid is fabricated, for example, from metal wire or threads composed of electrically conductive polymers. Both the process of actually fabricating such braids and the process of jacketing an electrical line or electrical cable with a braid of this type requires some effort which is reflected in high fabrication costs.

While lines and cables jacketed with a wire braid are in fact characterized by high flexibility, they do not possess the optimal shielding. Optimal shielding is achieved only by using a solid jacket, such as that found in a solid-jacket coaxial line, also called a semi-rigid coaxial line. In a solid-jacket coaxial line, the shielding outer line is made in a semi-rigid form, using copper tubing, for example.

The more flexible the implementation of a shielded line, the less impervious is the conductor to HF, especially in the high frequency range. The more impervious a line is in its ability to provide shielding from electromagnetic fields, the less flexibility it possesses. Any improvement in one of the two parameters, flexibility and HF imperviousness, automatically results in a diminution of the other parameter. It is thus impossible to combine both high flexibility and optimal shielding in one electrical line.

The goal of the invention is therefore to design an electrical line so as to combine both high flexibility and high shielding, while at the same time reducing the cost of fabrication significantly below that of shielded lines of prior art.

The invention achieves this goal through the features indicated in claim 1 by providing at least one ground conductor which is exposed at at least one site, by vapor-depositing a metal layer on the electrical line which is also vapor-deposited on the exposed site of the ground conductor, such that the metal layer deposited on the line and shielding the line can be connected to ground through a ground line.

The electrical line according to the invention is composed of at least one insulated conductor on which, for example, electrical signals are transmitted for communications purposes, or on which an electrical current for the purpose of power transmission flows, and on which one ground conductor is created which is exposed at at least one site. A metal layer is vapor-deposited on the line according to the invention to provide electromagnetic shielding. Since the ground conductor is exposed at at least one site, this site, which functions as a contact, is also provided with a metal layer by vapor deposition. When the ground conductor is grounded, the metal layer surrounding the electrical line is thus also grounded.

Because the shielding according to the invention is achieved through a vapor-deposited metal layer, the line according to the invention is characterized both by high flexibility and by a completely HF-impervious shielding. In addition, the vapor deposition of a metal layer onto the electrical line results in significantly lower cost than does jacketing by a wire braid or a copper tube, with the result that the electrical line according to the invention is characterized by high flexibility, completely HF-impervious shielding, and low fabrication costs.

The following explains the invention in more detail based on embodiments illustrated in the figures.

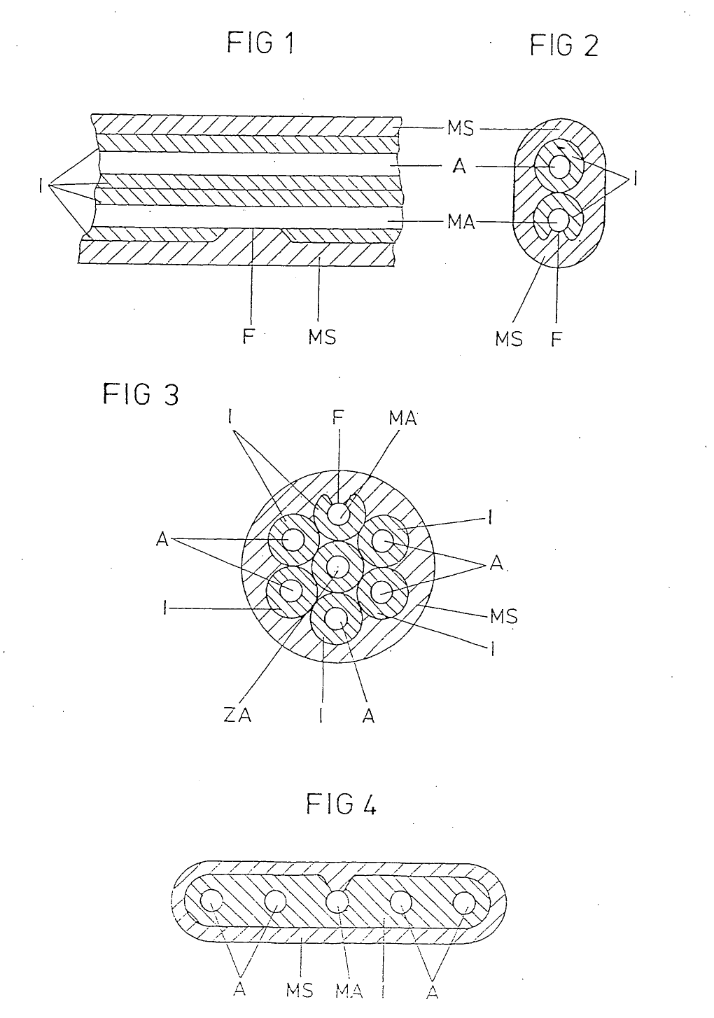

FIG. 1 is a lengthwise cross section through an embodiment of a cable according to the invention including a conductor and a ground conductor;

FIG. 2 is a cross section through the embodiment;

FIG. 3 is a cross section through an embodiment of a cable harness according to the invention;

FIG. 4 is a cross section through an embodiment of a flat cable according to the invention.

FIG. 1 is a cross section through an embodiment of a cable according to the invention including a conductor and a ground conductor.

A conductor A for the purpose of transmitting communications signals or power is surrounded by an insulation layer I. A ground conductor MA routed parallel to conductor A is similarly surrounded by an insulation layer I. Ground conductor MA is exposed at a site F. A metal layer MS is applied by vapor deposition to the line, which layer surrounds the line and is vapor-deposited directly onto ground conductor MA such that ground conductor MA is electrically connected to metal layer MS which shields the line. By connecting ground conductor MA to ground, the line is effectively shielded.

FIG. 2 is a cross section through the embodiment of FIG. 1.

FIG. 3 is a cross section through an embodiment of a cable harness according to the invention.

Multiple conductors A and a ground conductor MA are arranged around a central conductor ZA, the ground conductor being exposed at a site F. All the conductors A as well as ground conductor MA are surrounded by insulation layer I. However, ground conductor MA is exposed at a site F. The line composed of conductors A, ZA, and MA is surrounded by a vapor-deposited metal layer MS which is grounded.

FIG. 4 is a cross section through an embodiment of a flat cable according to the invention.

Multiple conductors A as well as ground conductor MA are embedded side by side within insulation layer I. Ground conductor MA is exposed at a site F. A metal layer MS is applied by vapor deposition to the surface of insulation layer I, which metal layer is vapor-deposited at exposed site F directly onto ground conductor MA which is grounded.

The electrical line according to the invention is suitable, for example, for installation in vehicles. It is characterized by high flexibility, complete electromagnetic shielding, and low fabrication cost.

List of Reference Characters

A conductor
F exposed site
I insulation layer
MA ground conductor
MS vapor-deposited metal layer
ZA central conductor

1. Electrical line comprising at least one insulated conductor, characterized in that at least one ground conductor is provided which is exposed at least one site, that a metal layer is applied by vapor deposition onto the electrical line, which layer is also vapor-deposited onto the exposed site of the ground conductor such that the metal layer vapor-deposited onto the line and shielding the line can be connected through the ground conductor to ground.

2. Electrical line according to claim 1, wherein ground conductor is completely exposed.

3. Electrical line according to claim 1, wherein the vapor-deposited metal layer is provided as the ground conductor.

4. Electrical line according to claims 1, wherein a metal layer is applied by vapor deposition onto a cable harness having a ground conductor which is exposed at at least one site.

5. Electrical line according to claims 1, wherein a metal layer is applied by vapor deposition onto a flat cable having a ground conductor which is exposed at least one site.

6. Electrical line according to claims 1, wherein a metal layer is applied by vapor deposition onto a flex line having a ground conductor which is exposed at least one site.

7. Electrical line according claim 6, wherein the electrical line is intended for installation in a motor vehicle.
